(19) United States
(12) Patent Application Publication
(10) Pub. No.: US 2026/0322409 A1
(43) Pub. Date: Oct. 15, 2026

(54) DIPLEXER AND ELECTRONIC DEVICE INCLUDING SAME

(71) Applicant: Samsung Electronics Co., Ltd., Suwon-si (KR)

(72) Inventors: Dongil YANG, Suwon-si (KR); Seonjun KIM, Suwon-si (KR); Yohan MOON, Suwon-si (KR); Mincheol KIM, Suwon-si (KR); Taeyoung KIM, Suwon-si (KR); Hyoseok NA, Suwon-si (KR)

(21) Appl. No.: 19/685,859

(22) Filed: May 22, 2026

Related U.S. Application Data
(63) Continuation of application No. PCT/KR2024/018901, filed on Nov. 26, 2024.

(30) Foreign Application Priority Data
Nov. 30, 2023 (KR) 10-2023-0171711
Mar. 12, 2024 (KR) 10-2024-0034778

(51) Int. Cl. H04B 1/00; H03H 9/02; H04B 1/40

(52) U.S. Cl. CPC H04B 1/0057; H03H 9/02; H04B 1/40

(57) ABSTRACT

A diplexer is provided. The diplexer includes a first terminal configured to be connected with an external radio frequency (RF) signal path of the diplexer, a second terminal electrically connected with the first terminal via an internal first RF signal path of the diplexer, a third terminal electrically connected with the first terminal via an internal second RF signal path, a first filter circuit configured to form at least a portion of the first RF signal path and pass signals in a first frequency band lower than a first specified frequency, and a second filter circuit configured to form at least a portion of the second RF signal path and pass signals in a second frequency band higher than a second specified frequency, wherein the first filter circuit includes a first acoustic resonator configured not to pass a third frequency band, and a first inductor and capacitor (LC) filter connected in series with the first acoustic resonator and configured to pass a frequency band lower than the first specified frequency, wherein the second filter circuit includes a second acoustic resonator configured not to pass a fourth frequency band, and a second LC filter connected in series with the second acoustic resonator and configured to pass a frequency band higher than the second specified frequency, and wherein the first specified frequency is a frequency lower than the second specified frequency.

### CROSS-REFERENCE TO RELATED APPLICATION(S)

This application is a continuation application, claiming priority under 35 U.S.C. § 365(c), of an International application No. PCT/KR 2024/018901, filed on Nov. 26, 2024, which is based on and claims the benefit of a Korean patent application number 10-2023-0171711, filed on Nov. 30, 2023, in the Ministry of Intellectual Property (MOIP), and of a Korean patent application number 10-2024-0034778, filed on Mar. 12, 2024, in the MOIP, the disclosure of each of which is incorporated by reference herein in its entirety.

### BACKGROUND

### 1. Field

The disclosure relates to a diplexer and an electronic device including the same.

### 2. Description of Related Art

An electronic device for performing wireless communication may wirelessly transmit and receive a radio frequency (RF) signal of one or more frequency bands via its antenna. To transmit and receive more pieces of information during the same time, the electronic device may use RF signals using a plurality of frequency bands. The electronic device may receive signals of the plurality of frequency bands based on carrier aggregation. The electronic device may receive signals of the plurality of frequency bands based on dual connectivity (DC).

As functionality of a portable electronic device, such as a mobile phone, increases, the electronic device may support wireless communication of various protocols. The electronic device may receive signals of the plurality of frequency bands according to the wireless communication of the various protocols. In an example, the plurality of frequency bands used by the electronic device may be frequency bands adjacent to each other.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a diplexer and an electronic device including the same.

Additional aspects will be set forth in part in the description which follows and, in part, will be apparent from the description, or may be learned by practice of the presented embodiments.

In accordance with an aspect of the disclosure, a diplexer is provided. The diplexer includes a first terminal configured to be connected with an external radio frequency (RF) signal path of the diplexer, a second terminal electrically connected with the first terminal via an internal first RF signal path of the diplexer, a third terminal electrically connected with the first terminal via an internal second RF signal path, a first filter circuit configured to form at least a portion of the first RF signal path and pass signals of a first frequency band lower than a first specified frequency, and a second filter circuit configured to form at least a portion of the second RF signal path and pass signals of a second frequency band higher than a second specified frequency, wherein the first filter circuit includes a first acoustic resonator configured not to pass a third frequency band and a first inductor and capacitor (LC) filter connected in series with the first acoustic resonator and configured to pass a frequency band lower than the first specified frequency, wherein the second filter circuit includes a second acoustic resonator configured not to pass a fourth frequency band and a second LC filter connected in series with the second acoustic resonator and configured to pass a frequency band higher than the second specified frequency, and wherein the first specified frequency is a frequency lower than the second specified frequency.

In accordance with another aspect of the disclosure, an apparatus for filtering a frequency of a signal is provided. The apparatus includes a plurality of terminals including a first terminal, a second terminal, and a third terminal, a low band filter circuit including a first acoustic resonator and a first inductor and capacitor (LC) filter connected in series with each other between the first terminal and the second terminal, and a high band filter circuit including a second acoustic resonator and a second LC filter connected in series with each other between the first terminal and the third terminal, wherein the low band filter circuit is configured to pass a first signal portion corresponding to a first frequency band lower than a first specified frequency for an input signal, wherein the high band filter circuit is configured to pass a second signal portion corresponding to a second frequency band higher than a second specified frequency for the input signal, and wherein the first specified frequency is lower than the second specified frequency.

In accordance with another aspect of the disclosure, a portable communication device is provided. The portable communication device includes an antenna, a transceiver, and a diplexing circuit, wherein the diplexing circuit includes a first terminal connected with at least one of a radio frequency (RF) signal path connected with one of the antenna or the transceiver or an external RF signal path of the diplexing circuit, a second terminal connected with the first terminal via an internal first RF signal path of the diplexing circuit, a third terminal connected with the first terminal via an internal second RF signal path of the diplexing circuit, a first filter circuit configured to form at least a portion of the first RF signal path and pass signals of a first frequency band lower than a first specified frequency, and a second filter circuit configured to form at least a portion of the second RF signal path and pass signals of a second frequency band higher than a second specified frequency, wherein the first specified frequency is a frequency lower than the second specified frequency, wherein the first filter circuit includes a first acoustic resonator configured not to pass a third frequency band, and a first inductor and capacitor (LC) filter connected in series with the first acoustic resonator and configured to pass a frequency band lower than the first specified frequency, and wherein the second filter circuit includes a second acoustic resonator configured not to pass a fourth frequency band, and a second LC filter connected in series with the second acoustic resonator and configured to pass a frequency band higher than the second specified frequency.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram illustrating a configuration of an electronic device according to an embodiment of the disclosure;

FIG. 2 is a drawing illustrating a configuration of an electronic device according to an embodiment of the disclosure;

FIGS. 3A and 3B are drawings illustrating intensity of signals transmitted and received by an electronic device according to various embodiments of the disclosure;

FIGS. 4A, 4B, and 4C are drawings illustrating a configuration of a diplexer according to various embodiments of the disclosure;

FIG. 5 illustrates frequency bands of signals transmitted and received by an electronic device according to an embodiment of the disclosure; and

FIG. 6 is a block diagram of an electronic device in a network environment according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi™) chip, a Bluetooth™ chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

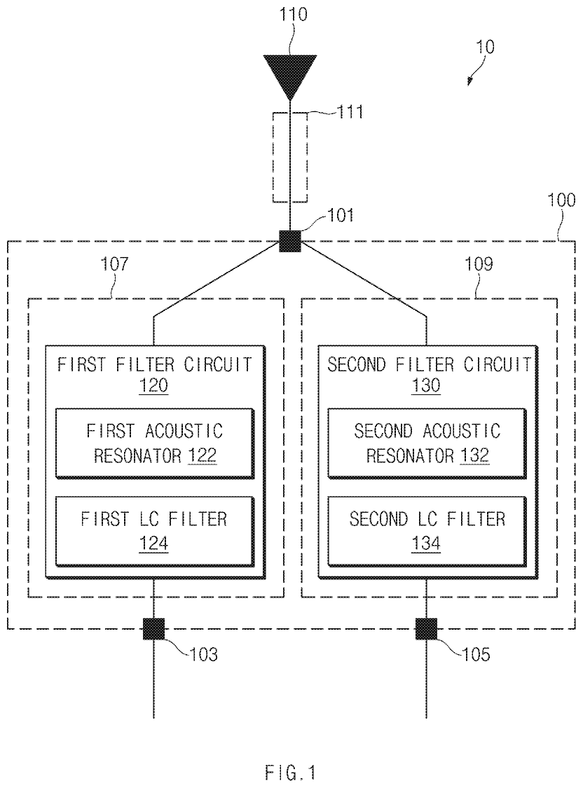

FIG. 1 is a block diagram illustrating a configuration of an electronic device according to an embodiment of the disclosure.

Referring to FIG. 1, an electronic device 10 may include a diplexer 100, an antenna 110, a first filter circuit 120, or a second filter circuit 130. In an example, the diplexer 100 included in the electronic device 10 may include a first terminal 101, a second terminal 103, a third terminal 105, an internal first RF signal path 107, and/or an internal second RF signal path 109. In the disclosure, examples will be described around the diplexer 100 for convenience of description. However, those skilled in the art will understand that embodiments of the disclosure are applicable to even an example of a multiplexer or a duplexer for processing a plurality of signals with different frequencies. For example, even when the electronic device 10 processes the plurality of signals with the different frequencies using the multiplexer or the duplexer, embodiments of the disclosure may be applied.

According to an embodiment, the electronic device 10 may transmit and receive signals corresponding to various frequency bands. In an example, the electronic device 10 may separate frequency bands of signals corresponding to various frequency bands or may alleviate interference and noise between a plurality of signals using the diplexer 100. The disclosure may reduce a loss between various communication band signals passing through the diplexer 100 and may improve different band rejection characteristics, when a frequency interval between wireless communication bands is narrow, using a new design structure of the diplexer 100 which plays a role as separation between frequencies in a radio frequency front end (RFFE) of wireless communication equipment or a terminal.

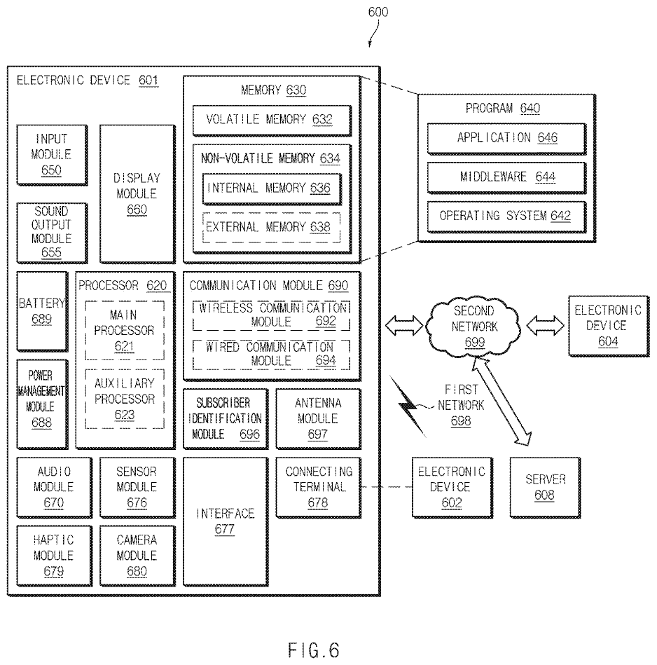

According to an embodiment, the electronic device 10 of FIG. 1 may correspond to, for example, an electronic device 601 of FIG. 6. The configurations of the electronic device 10, which will be described below in conjunction with FIG. 1, are an example and embodiments of the disclosure are not limited thereto. For example, the electronic device 10 may fail to include at least some (e.g., the first terminal 101 of FIG. 1) of the configurations illustrated in FIG. 1. For example, the electronic device 10 may further include another configuration (e.g., the configuration of the electronic device 601 of FIG. 6) other than the configurations illustrated in FIG. 1.

According to an embodiment, the diplexer 100 may distinguish and pass different frequency signals, such that the two or more different frequency signals are able to share a path (e.g., external RF signal path 111) of the one antenna 110. In an example, for a first frequency signal passing through the second terminal 103 and a second frequency signal passing through the third terminal 105, the diplexer 100 may reduce interference between the two signals (e.g., the first frequency signal or the second frequency signal) or leakage of the two signals (e.g., the first frequency signal or the second frequency signal) and may deliver the two signals (e.g., the first frequency signal or the second frequency signal) to the one antenna 110. In an example, the diplexer 100 may cause the first frequency signal and the second frequency signal to share the path (e.g., external RF signal path 111) between the first terminal 101 and the antenna 110. In an example, the first frequency signal described in the disclosure may correspond to a first RF signal, a low-band frequency signal, or a mid-band frequency signal and the second frequency signal may correspond to a second RF signal or a high-band frequency signal.

According to an embodiment, the diplexer 100 may cause the first frequency signal to pass through an external RF signal path 111 and the internal first RF signal path 107 and not to substantially pass through the third terminal 105. For example, the diplexer 100 may cause the first frequency signal to pass through a path including the second terminal 103, the first terminal 101, and the antenna 110 and not to substantially pass through the third terminal 105. For example, the diplexer 100 may cause a path including the second filter circuit 130 and the third terminal 105 to be in a substantial open circuit state, for the first frequency signal.

According to an embodiment, the diplexer 100 may cause the second frequency signal to pass through the external RF signal path 111 and the internal second RF signal path 109 and not to substantially pass through the second terminal 103. For example, the diplexer 100 may cause the second frequency signal to pass through a path including the third terminal 105, the first terminal 101, and the antenna 110 and not to substantially pass through the second terminal 103. For example, the diplexer 100 may cause a path including the first filter circuit 120 and the second terminal 103 to be in the substantial open circuit state, for the second frequency signal.

For example, the diplexer 100 may cause the first frequency signal to be applied to a path including the second terminal 103, the first terminal 101, and the antenna 110. In an example, the diplexer 100 may cause the first frequency signal not to be applied to the third terminal 105. For example, the diplexer 100 may cause the second frequency signal to be applied to a path including the third terminal 105, the first terminal 101, and the antenna 110. In an example, the diplexer 100 may cause the second frequency signal not to be applied to the second terminal 103.

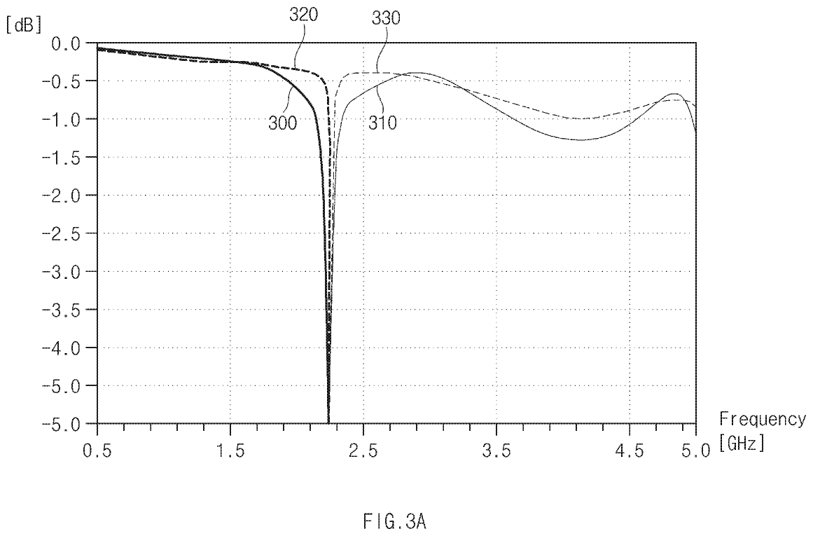

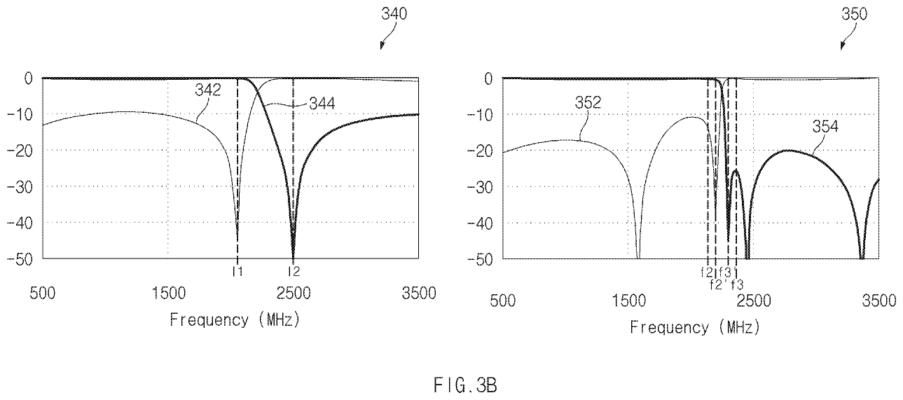

According to an embodiment, the diplexer 100 may distinguish frequency signals passing through the diplexer 100 on the basis of a cut-off frequency. In an example, the diplexer 100 may cause signals corresponding to a frequency lower than a first cut-off frequency to pass through the path including the second terminal 103, the first terminal 101, and the antenna 110, on the basis of the first cut-off frequency, and may cause signals corresponding to a frequency higher than a second cut-off frequency to pass through the path including the third terminal 105, the first terminal 101, and the antenna 110, on the basis of the second cut-off frequency. In an example, a first LC filter 124 may have the first cut-off frequency and a second LC filter 134 may have the second cut-off frequency. In an example, the cut-off frequencies of the first LC filter 124 and the second LC filter 134 may correspond to a cut-off frequency of the diplexer 100. A detailed description of the cut-off frequency will be described below in FIG. 3A.

According to an embodiment, the diplexer 100 may separate paths of the first frequency signal and the second frequency signal transmitted and received using the antenna 110. For example, the diplexer 100 may cause the first frequency signal received using the antenna 110 to be applied to the internal first RF signal path 107 and may cause the first frequency signal not to be applied to the third terminal 105. For example, the diplexer 100 may cause the second frequency signal received using the antenna 110 to be applied to the internal second RF signal path 109 and may cause the second frequency signal not to be applied to the second terminal 103.

According to an embodiment, the second terminal 103 may correspond to a terminal through which the first frequency signal transmitted and received by the diplexer 100 passes. In an example, the second terminal 103 may correspond to at least one node connected with the first filter circuit 120 included in the diplexer 100. For example, the first filter circuit 120 may include one or more nodes and the second terminal 103 may correspond to one of the one or more nodes. In an example, the terminal described in the disclosure may correspond to a port from which a signal is input and output. For example, the first terminal 101, the second terminal 103, and the third terminal 105 may correspond to a first port, a second port, and a third port, respectively.

According to an embodiment, the diplexer 100 may include at least one acoustic resonator (e.g., first acoustic resonator 122, second acoustic resonator 132). In an example, the diplexer including the acoustic resonator may have higher adjacent frequency signal distinguishment performance than a diplexer based on an inductor and a capacitor. In an example, the acoustic resonator (e.g., first acoustic resonator 122, second acoustic resonator 132) may be used in the form of a SAW filter using a surface acoustic wave (SAW) and a BAW filter using a bulk acoustic wave (BAW). In an example, because the acoustic resonator (e.g., first acoustic resonator 122, second acoustic resonator 132) uses an acoustic wave with a shorter wavelength than an electromagnetic wave at the same frequency, it may be made smaller in size to facilitate mass production.

According to an embodiment, the diplexer 100 may include a SAW filter and/or a BAW filter. In an example, the SAW filter included in the diplexer 100 may convert a signal, which is an electromagnetic wave at the speed of light, into a surface acoustic wave, which is a low-speed acoustic wave, and may then extract only a certain frequency. The SAW filter may have a narrow bandwidth of a passing frequency and may have an excellent characteristic at a frequency band boundary. In an example, the BAW filter included in the diplexer 100 may effectively filter a high-frequency signal. The BAW filter may have a relatively low insertion loss to alleviate signal attenuation. In an example, the BAW filter may have high frequency selectivity even in a narrow bandwidth to effectively separate a frequency band to pass only a desired signal.

According to an embodiment, the first acoustic resonator 122 may correspond to a filter for blocking a signal of a set frequency band and passing a signal outside the set frequency band. In an example, the first acoustic resonator 122 may correspond to a notch filter or a band reject filter. For example, the first acoustic resonator 122 may be used to block a signal of a frequency band which causes unnecessary interference. In an example, a stop band of the first acoustic resonator 122 may include a frequency band adjacent to the cut-off frequency of the diplexer 100. In an example, the stop band of the first acoustic resonator 122 may correspond to the lowest frequency band of a frequency band passed by the second LC filter 134. In an example, the stop band of the first acoustic resonator 122 may be included in a transition band of frequency signal intensity formed by the first LC filter 124 or a transition band of frequency signal intensity formed by the second LC filter 134.

According to an embodiment, the acoustic resonator described in the disclosure may correspond to a band stop filter for blocking a signal of a certain frequency band. For example, the first acoustic resonator 122 and the second acoustic resonator 132 may correspond to a first band stop filter and a second band stop filter. In an example, the first acoustic resonator 122 may form at least a part of a first notch filter and the second acoustic resonator 132 may form at least a part of a second notch filter.

According to an embodiment, the third terminal 105 may correspond to a terminal through which the second frequency signal transmitted and received by the diplexer 100 passes. In an example, the third terminal 105 may correspond to at least one node connected with the second filter circuit 130 included in the diplexer 100. For example, the second filter circuit 130 may include one or more nodes and the third terminal 105 may correspond to one of the one or more nodes.

According to an embodiment, the second acoustic resonator 132 may correspond to a filter for blocking the signal of the set frequency band and passing the signal outside the set frequency band. In an example, the second acoustic resonator 132 may correspond to a notch filter or a band reject filter. For example, the second acoustic resonator 132 may be used to block the signal of the frequency band which causes the unnecessary interference. In an example, a stop band of the second acoustic resonator 132 may include a frequency band adjacent to the cut-off frequency of the diplexer 100. In an example, the stop band of the second acoustic resonator 132 may correspond to the highest frequency band of a frequency band passed by the first LC filter 124. In an example, the stop band of the second acoustic resonator 132 may be included in the transition band of the frequency signal intensity formed by the first LC filter 124 or the transition band of the frequency signal intensity formed by the second LC filter 134. A detailed description of the transition band will be described below in FIG. 3A.

According to an embodiment, the antenna 110 may correspond to an antenna shared by signals passed by the diplexer 100. In an example, the antenna 110 may wirelessly receive a signal of a plurality of set frequency bands. For example, the antenna 110 may include an antenna array or an antenna module. In an example, the antenna 110 may transmit and receive a signal of a first frequency band and may simultaneously transmit and receive a signal of a second frequency band. The antenna 110 may transmit and receive signals included in a plurality of band frequencies adjacent to the plurality of set frequency bands. In an example, the antenna 110 may receive signals included in some of a plurality of channels included in one band frequency.

According to an embodiment, the first LC filter 124 may separate the first frequency band from the second frequency band. The first LC filter 124 may pass a signal with a frequency lower than the first cut-off frequency. For example, the first LC filter 124 may pass the first frequency band. In an example, the first LC filter 124 may be electrically connected with a duplexer. For example, the first frequency signal may be delivered to the duplexer via the first LC filter 124. According to an embodiment, the LC filter described in the disclosure may correspond to a band pass filter for passing a signal of a certain frequency band. For example, the first LC filter 124 and the second LC filter 134 may correspond to a low band pass filter and a high band pass filter.

According to an embodiment, the second LC filter 134 may separate the second frequency band from the first frequency band. The second LC filter 134 may pass a signal with a frequency higher than the second cut-off frequency. For example, the second LC filter 134 may pass the second frequency band. In an example, the second LC filter 134 may be electrically connected with the duplexer. For example, the second frequency signal may be delivered to the duplexer via the second LC filter 134.

The electronic device 10 according to an embodiment may further include a printed circuit board (PCB). The first LC filter 124 and the second LC filter 134 may be arranged on the PCB. In an example, the diplexer 100 may be disposed on the PCB or may be formed as one module. For example, the diplexer 100 may form at least a part of a circuit included in the electronic device 10. For example, the diplexer 100 may be one module, which may be disposed on the electronic device 10 or may be detached from the electronic device 10.

According to an embodiment, the first LC filter 124 may correspond to a low pass filter and the second LC filter 134 may correspond to a high pass filter. In an example, the LC filter (e.g., first LC filter 124, second LC filter 134) may use an inductor and/or a capacitor, which are/is configuration(s) which maintain(s) electromagnetic energy to be used in a low pass filter and/or a high pass filter. Thus, as a frequency of a signal passing through the LC filter (e.g., first LC filter 124, second LC filter 134) is high or low, the LC filter (e.g., first LC filter 124, second LC filter 134) may make impedance corresponding it to be close to infinity or close to 0. In an example, because the LC filter (e.g., first LC filter 124, second LC filter 134) uses the inductor and/or the capacitor to facilitate energy conservation other than a loss due to the inductor and/or capacitor configuration itself, a loss may be small in a process of processing a wideband frequency signal.

According to an embodiment, the acoustic resonator (e.g., first acoustic resonator 122, second acoustic resonator 132) may correspond to a band stop filter. In an example, the acoustic resonator may have high energy conversion efficiency using a resonance operation of a frequency. In an example, the acoustic resonator (e.g., first acoustic resonator 122, second acoustic resonator 132) may pass a signal with a limited frequency bandwidth and may cut off another frequency, using a resonance frequency and/or an antiresonance frequency of the frequency to have high selectivity performance. In an example, the acoustic resonator (e.g., first acoustic resonator 122, second acoustic resonator 132) may correspond to a filter for processing a narrowband frequency signal.

According to an embodiment, the diplexer 100 may include an LC filter (e.g., first LC filter 124, second LC filter 134) of an inductor and capacitor configuration showing excellent IL performance in the wideband and an acoustic resonator (e.g., first acoustic resonator 122, second acoustic resonator 132) showing excellent band selectivity/rejection performance in the narrowband. In an example, the diplexer 100 may ensure band selectivity/rejection performance in the narrowband using the acoustic resonator (e.g., first acoustic resonator 122, second acoustic resonator 132) and may ensure IL performance in the wideband using the LC filter (e.g., first LC filter 124, second LC filter 134) of the inductor and capacitor configuration. In an example, the diplexer 100 according to the disclosure may more precisely distinguish different frequency signals in a narrower frequency band than a diplexer which uses an existing filter based on the inductor and the capacitor.

According to an embodiment, the first acoustic resonator 122 may be connected in series or in parallel with at least a partial configuration of the first filter circuit 120. For example, the first filter circuit 120 may correspond to a circuit in which the first acoustic resonator 122 and the first LC filter 124 are connected in series or in parallel with each other. In an example, the second acoustic resonator 132 may be connected in series or in parallel with at least a partial configuration of the second filter circuit 130. For example, the second filter circuit 130 may correspond to a circuit in which the second acoustic resonator 132 and the second LC filter 134 are connected in series or in parallel with each other.

A diplexer 100 according to an embodiment may include a first terminal 101 configured to be connected with an external RF signal path 111 of the diplexer 100, a second terminal 103 electrically connected with the first terminal 101 via an internal first RF signal path 107 of the diplexer 100, a third terminal 105 electrically connected with the first terminal 101 via an internal second RF signal path 109, a first filter circuit 120 configured to form at least a portion of the internal first RF signal path 107 and substantially pass signals of a first frequency band lower than a first specified frequency f2, and a second filter circuit 130 configured to form at least a portion of the internal second RF signal path 109 and substantially pass signals of a second frequency band higher than a second specified frequency f3. The first filter circuit 120 may include a first acoustic resonator 122 configured not to pass a third frequency band and a first LC filter 124 connected in series with the first acoustic resonator 122 and configured to pass a frequency band lower than the first specified frequency f2. The second filter circuit 130 may include a second acoustic resonator 132 configured not to pass a fourth frequency band and a second LC filter 134 connected in series with the second acoustic resonator 132 and configured to pass a frequency band higher than the second specified frequency f3. The first specified frequency f2 may be lower than the second specified frequency f3.

In the diplexer 100 according to an embodiment, the first filter circuit 120 may further include an inductor connected between the first terminal 101 and the first acoustic resonator 122 and the second filter circuit 130 may further include a capacitor connected between the first terminal 101 and the second acoustic resonator 132.

The diplexer 100 according to an embodiment may be configured not to pass a fifth frequency band corresponding to between the first specified frequency f2 and the second specified frequency f3. A bandwidth value of the fifth frequency band compared to a center frequency value of the fifth frequency band may be set to 5% or less.

According to an embodiment, when setting a frequency bandwidth value of a frequency to be cut off to 10% or less, compared to a center frequency value of the frequency to be cut off, in a high-frequency band (e.g., a band of 2 GHz or more), the diplexer 100 not including the first acoustic resonator 122 or the second acoustic resonator 132 may have a degraded filter characteristic. According to an embodiment, the diplexer 100 including the first acoustic resonator 122 or the second acoustic resonator 132 may implement the frequency bandwidth value of the frequency to be cut off as 10% or less, compared to the center frequency value of the frequency to be cut off, even without harming a filter characteristic, in the high-frequency band (e.g., the band of 2 GHz or more). For example, the frequency bandwidth value of the frequency to cut off may correspond to 5% or less, compared to the center frequency value of the frequency to be cut off by the diplexer 100 including the first acoustic resonator 122 or the second acoustic resonator 132, for an interval around 2 GHz.

According to an embodiment, the frequency bandwidth value of the frequency to be cut off, compared to the center frequency value of the frequency to be cut off by the diplexer 100, may correspond to an adjacent frequency separation characteristic value. In an example, as the adjacent frequency separation characteristic value corresponds to lower %, it may correspond to a diplexer which separates an adjacent frequency signal such that an insertion loss of the adjacent frequency signal is small, in a narrower band. In an example, a detailed calculation process, a graph, and a detailed description of the frequency bandwidth value of the frequency to be cut off, compared to the center frequency value of the frequency to be cut off by the diplexer 100, will be given below with reference to FIG. 3B.

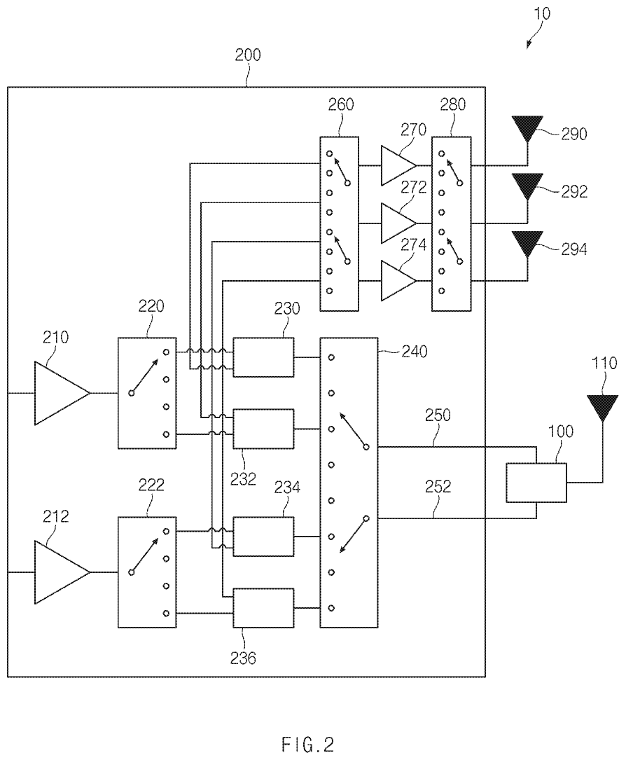

FIG. 2 is a drawing illustrating a configuration of an electronic device according to an embodiment of the disclosure.

Referring to FIG. 2, an electronic device 10 may include a front end module 200. The front end module 200 may include one or more first amplifiers (e.g., first amplifiers 210 and 212), one or more switches (e.g., switches 220, 222, 240, 260, and 280), one or more first to fourth filters (e.g., first filter 230, second filter 232, third filter 234, and fourth filter 236), and one or more second amplifiers (e.g., second amplifiers 270, 272, and 274). In an example, the front end module 200 may be electrically connected with a diplexer 100 electrically connected with an antenna 110. Furthermore, the front end module 200 may be electrically connected with one or more second antennas (e.g., antennas 290, 292, and 294).

According to an embodiment, referring to FIG. 1 together, the front end module 200 may transmit a mid-band frequency signal to the diplexer 100 using a path 250 for connecting the front end module 200 and a second terminal 103 of FIG. 1 and may receive a high-band frequency signal from the diplexer 100 using a path 252 for connecting the front end module 200 and a third terminal 105 of FIG. 1. In an example, when transmitting and receiving the mid-band frequency signal and the high-band frequency signal using one antenna, the electronic device 10 may use a wideband filter, such as the diplexer 100 capable of simultaneously transmitting and receiving the mid-band frequency signal and the high-band frequency signal. In FIG. 2, it is assumed that the front end module 200 transmits the mid-band frequency signal using the path for connecting the front end module 200 and the second terminal 103 of FIG. 1, receives the high-band frequency signal using the path 252 for connecting the front end module 200 and the third terminal 105 of FIG. 1, and transmits and receives the mid-band frequency signal and the high-band frequency signal using the one antenna 110. However, the diplexer 100 may be variously used according to the used frequency band or types of the transmitted and received signals.

According to an embodiment, the diplexer 100 used to transmit and receive the mid-band frequency signal and the high-band frequency signal using the one antenna 110 may have a larger adjacent frequency band in which frequency signals of two bands diverge due to a material limitation based on an inductor including a ceramic material and a capacitor than a band with a relatively different signal loss.

According to an embodiment, each of the one or more first amplifiers (e.g., first amplifiers 210 and 212) may be connected with at least one terminal included in a transceiver. Each of the one or more first amplifiers (e.g., first amplifiers 210 and 212) may include a power amplifier (PA) or a transmit amplifier. In an example, each of the one or more first amplifiers (e.g., first amplifiers 210 and 212) may amplify a signal output from the transceiver. Each of the one or more first amplifiers (e.g., first amplifiers 210 and 212) may obtain one or more transmit signals with a first frequency band a second frequency band from the transceiver. Each of the one or more first amplifiers (e.g., first amplifiers 210 and 212) may amplify and provide the diplexer 100 with one or more transmit signals. Each of the one or more first amplifiers (e.g., first amplifiers 210 and 212) may be a multi-mode multi band PA (MMMB PA) capable of amplifying signals included in a plurality of frequency bands. Alternatively, each of the one or more first amplifiers (e.g., first amplifiers 210 and 212) may amplify a signal of a set frequency band. The electronic device 10 according to various embodiments disclosed in the disclosure may include various numbers of first amplifiers (e.g., first amplifiers 210 and 212) for amplifying a transmit signal.

According to an embodiment, the one or more first to fourth filters (e.g., first filter 230, second filter 232, third filter 234, and fourth filter 236) may filter a signal of a radio frequency band, which is transmitted and received from one or more antennas (e.g., antennas 290, 292, 294, and 110). For example, the first to fourth filters (e.g., first filter 230, second filter 232, third filter 234, and fourth filter 236) may be SAW filters or BAW filters.

According to an embodiment, the path 250 for connecting the front end module 200 and the second terminal 103 of FIG. 1 may correspond to a path through which a first frequency signal delivered from the front end module 200 to the diplexer 100 passes. Alternatively, the path 250 for connecting the front end module 200 and the second terminal 103 of FIG. 1 may correspond to a path through which the first frequency signal delivered from the diplexer 100 to the front end module 200 passes. In an example, referring to FIG. 1 together, the path 250 for connecting the front end module 200 and the second terminal 103 of FIG. 1 may be electrically connected with a first LC filter 124. In an example, the path 252 for connecting the front end module 200 and the third terminal 105 of FIG. 1 may correspond to a path through which a second frequency signal delivered from the front end module 200 to the diplexer 100 passes. Alternatively, the path 252 for connecting the front end module 200 and the third terminal 105 of FIG. 1 may correspond to a path through which the second frequency signal delivered from the diplexer 100 to the front end module 200 passes. In an example, the path 252 for connecting the front end module 200 and the third terminal 105 of FIG. 1 may be electrically connected with a second LC filter 134.

According to an embodiment, the one or more second amplifiers (e.g., second amplifiers 270, 272, and 274) may amplify one or more receive signals. The one or more second amplifiers (e.g., second amplifiers 270, 272, and 274) may be connected with at least one terminal included in the transceiver. For example, the one or more second amplifiers (e.g., second amplifiers 270, 272, and 274) may include a receive amplifier or a low noise amplifier (LNA).

In an embodiment, the one or more second amplifiers (e.g., second amplifiers 270, 272, and 274) may amplify a receive signal obtained by the transceiver. In an example, the one or more second amplifiers (e.g., second amplifiers 270, 272, and 274) may obtain one or more receive signals with a first receive frequency band and a second receive frequency band from at least one duplexer module included in the electronic device 10. The one or more second amplifiers (e.g., second amplifiers 270, 272, and 274) may amplify and provide the transceiver with one or more receive signals. The one or more second amplifiers (e.g., second amplifiers 270, 272, and 274) may be multi-mode multi band PAs. Alternatively, the one or more second amplifiers (e.g., second amplifiers 270, 272, and 274) may amplify a signal of a set frequency band. The electronic device 10 according to various embodiments disclosed in the disclosure may include various numbers of second amplifiers (e.g., second amplifiers 270, 272, and 274) for amplifying a receive signal.

According to an embodiment, in an embodiment, one or more amplifiers may amplify a receive signal obtained by the transceiver. In an example, the one or more amplifiers may obtain one or more receive signals with the first receive frequency band and the second receive frequency band from at least one duplexer module or the diplexer included in the electronic device 10. For example, the one or more second amplifiers (e.g., second amplifiers 270, 272, and 274) may obtain one or more receive signals with the first receive frequency band and the second receive frequency band from the at least one duplexer module or the diplexer 100 included in the electronic device 10.

According to an embodiment, a receive signal of a certain frequency band received from any one antenna 110 among the one or more antennas (e.g., antennas 110, 290, 292, and 294) may be delivered to the transceiver. The receive signal received from the any one antenna 110 may be filtered by the at least one duplexer module included in the electronic device 10. The filtered receive signal may be immediately delivered to the transceiver or may be delivered to the transceiver via a receive amplifier.

According to an embodiment, a receive signal of another frequency band received from the antennas (e.g., antennas 290, 292, and 294) may be delivered to the one or more second amplifiers (e.g., second amplifiers 270, 272, and 274) using the switch 280. The receive signal delivered to the one or more second amplifiers (e.g., second amplifiers 270, 272, and 274) may be amplified and delivered to the transceiver. The transceiver may receive signals of various frequency bands from at least one amplifier among the one or more second amplifiers (e.g., second amplifiers 270, 272, and 274).

According to an embodiment, the receive signal of the other frequency band received from the antennas (e.g., antennas 290, 292, and 294) may be selectively delivered to a corresponding filter among the one or more first to fourth filters (e.g., first filter 230, second filter 232, third filter 234, and fourth filter 236), using switches (e.g., switches 260 and 280) located between the antennas (e.g., antennas 290, 292, and 294) and the filters (e.g., first filter 230, second filter 232, third filter 234, and fourth filter 236). The receive signal delivered to the corresponding filter among the first to fourth filters (e.g., first filter 230, second filter 232, third filter 234, and fourth filter 236) may be filtered based on a resonance frequency band of the corresponding filter.

The electronic device 10 according to an embodiment may further include a front end module configured to transmit or receive a signal with the first frequency band and a signal with the second frequency band via the diplexer 100.

FIGS. 3A and 3B are drawings illustrating intensity of signals transmitted and received by an electronic device according to various embodiments of the disclosure.

Referring to FIGS. 1 and 3A together, intensity of a mid-band frequency signal and a high-band frequency signal passing through a diplexer 100 may vary depending on a design structure of the diplexer 100. In an example, when a first acoustic resonator 122 and a second acoustic resonator 132 are excluded from the configuration of the diplexer 100, intensity 300 of a mid-band frequency signal and intensity 310 of a high-band frequency signal, which pass through a diplexer not including the first acoustic resonator 122 and the second acoustic resonator 132, may indicate the same intensity as sold lines of FIG. 3A. In an example, when the first acoustic resonator 122 and the second acoustic resonator 132 are included, like the configuration of the diplexer 100, intensity 320 of the mid-band frequency signal and intensity 330 of the high-band frequency signal, which pass through the diplexer 100, may indicate the same intensity as dotted lines of FIG. 3A.

According to an embodiment, in the disclosure, examples are described around the mid-band frequency signal and the high-band frequency signal for convenience of description. However, those skilled in the art may understand that embodiments of the disclosure are applicable to even examples of a low-band frequency signal and the mid-band frequency signal or the low-band frequency signal and the high-band frequency signal. For example, even when processing signals of adjacent frequency bands, such as the low-band frequency signal and the mid-band frequency signal, embodiments of the disclosure may be applied. In an example, the mid-band frequency signal may correspond to a first frequency band and the high-band frequency signal may correspond to a second frequency band.

According to an embodiment, referring to the intensity 300 of the mid-band frequency signal and the intensity 310 of the high-band frequency signal, which correspond to the sold lines of FIG. 3A, it may be seen that a signal loss or an insertion loss (IL) in an interval where two bands are adjacent to each other is greater than a signal loss or an insertion loss in another frequency band. As described above, this may be seen as a material limitation based on an inductor using ceramic and a capacitor. In an example, referring to FIG. 1 together, the first acoustic resonator 122 and the second acoustic resonator 132 are included like the configuration of the diplexer 100, a change in intensity of a signal according to a frequency of a transition band appearing in a frequency separation interval may steeply appear. For example, when the first acoustic resonator 122 and the second acoustic resonator 132 are included in the configuration of the diplexer 100, a transition bandwidth may be reduced.

According to an embodiment, referring to FIG. 1 together, a cut-off frequency of a first LC filter 124 may correspond to a frequency corresponding to a point where the output of the input first frequency signal is reduced by about 3 dB. Furthermore, a cut-off frequency of a second LC filter 134 may correspond to a frequency corresponding to a point where the output of the input second frequency signal is reduced by about 3 dB. In an example, a variance according to an intensity (e.g., intensity 300) of a first signal corresponding to the cut-off frequency of the first LC filter 124 may appear in a relatively gentle form, when the first acoustic resonator 122 is not included in the diplexer 100, and a variance according to an intensity (e.g., intensity 320) of the first signal corresponding to the cut-off frequency of the first LC filter 124 may appear in a relatively sharp form, when the first acoustic resonator 122 is included in the diplexer 100. In an example, a variance according to an intensity (e.g., intensity 310) of a second signal corresponding to the cut-off frequency of the second LC filter 134 may appear in a relatively gentle form, when the second acoustic resonator 132 is not included in the diplexer 100, and a variance according to an intensity (e.g., intensity 330) of the second signal corresponding to the cut-off frequency of the second LC filter 134 may appear in a relatively sharp form, when the second acoustic resonator 132 is included in the diplexer 100.

According to an embodiment, referring to FIG. 1 together, when a mid-band frequency signal (e.g., the first frequency signal) passes through a diplexer not including the first acoustic resonator 122, the mid-band frequency signal may correspond to the intensity 300 of the solid-line mid-band frequency signal, a frequency corresponding to a point where the intensity 300 of the mid-band frequency signal is degraded by 3 dB by the first LC filter 124 may correspond to 2.24 GHz, and the cut-off frequency of the first LC filter 124 may correspond to 2.24 GHz. Meanwhile, when the mid-band frequency signal passes through the diplexer 100 including the first acoustic resonator 122, the mid-band frequency signal may correspond to the intensity 320 of the dotted-line mid-band frequency signal and a gradient of the intensity (e.g., intensity 300, intensity 320) of the mid-band frequency signal may vary depending on whether the first acoustic resonator 122 is included. The gradient of the intensity of the frequency signal may correspond to a variance in intensity of a signal according to a frequency.

According to an embodiment, referring to FIG. 1 together, when a high-band frequency signal (e.g., the second frequency signal) passes through a diplexer not including the second acoustic resonator 132, the high-band frequency signal may correspond to the intensity 310 of the solid-line high-band frequency signal, a frequency corresponding to a point where the intensity 330 of the high-band frequency signal is degraded by 3 dB by the second LC filter 134 may correspond to 2.25 GHz, and the cut-off frequency of the second LC filter 134 may correspond to 2.25 GHz. Meanwhile, when the high-band frequency signal passes through the diplexer 100 including the second acoustic resonator 132, the high-band frequency signal may correspond to the intensity 330 of the dotted-line high-band frequency signal and a gradient of the intensity (e.g., intensity 310, intensity 330) of the high-band frequency signal may vary depending on whether the second acoustic resonator 132 is included. The mid-band frequency signal and the high-band frequency signal in the disclosure are a description indicating an example of adjacent frequency signals, which are not limited to a certain frequency band. For example, the mid-band frequency signal and the high-band frequency signal may correspond to a low-band frequency signal and the mid-band frequency signal. In an example, the mid-band frequency signal may correspond to the first frequency band and the high-band frequency signal may correspond to the second frequency band.

According to an embodiment, the transition band may correspond to a frequency interval where a variance in intensity of a signal according to a frequency is relatively high, between a frequency band to be passed by a band stop filter and a frequency band to be cut off. In an example, referring to FIG. 1 together, a transition bandwidth of the mid-band frequency signal may be more reduced when the diplexer 100 includes the first acoustic resonator 122, than when the diplexer 100 does not include the first acoustic resonator 122. In an example, referring to FIG. 1 together, a transition bandwidth of the high-band frequency signal may be more reduced when the diplexer 100 includes the second acoustic resonator 132, than when the diplexer 100 does not include the second acoustic resonator 132. In an example, an interval between the cut-off frequency of the first LC filter 124 and the cut-off frequency of the second LC filter 134 may be more reduced when the diplexer 100 includes the first acoustic resonator 122 and the second acoustic resonator 132, than when the diplexer 100 does not include the first acoustic resonator 122 and the second acoustic resonator 132.

A stop band of the first acoustic resonator 122 according to an embodiment may be set to reduce the transition bandwidth of the second LC filter 134 and a stop band of the second acoustic resonator 132 may be set to reduce the transition bandwidth of the first LC filter 124.

The first acoustic resonator 122 according to an embodiment may be configured to attenuate at least a portion of a signal transmitted from the antenna 110 to the first LC filter 124 and the second acoustic resonator 132 may be configured to attenuate at least a portion of a signal transmitted from the second LC filter 134 to the antenna 110.

Referring to FIGS. 1 and 3B together, intensity of a mid-band frequency signal and a high-band frequency signal passing through the diplexer 100 may vary depending on the design structure of the diplexer 100. In an example, an intensity graph of a frequency signal passing through the diplexer may have the same form as a signal intensity graph 340 for each frequency corresponding to a diplexer not including the first acoustic resonator (e.g., first acoustic resonator 122) and the second acoustic resonator (e.g., second acoustic resonator 132) or a signal intensity graph 350 for each frequency corresponding to a diplexer including the first acoustic resonator (e.g., first acoustic resonator 122) and the second acoustic resonator (e.g., second acoustic resonator 132).

According to an embodiment, referring to FIG. 3A together, the signal intensity graph 340 for each frequency corresponding to the diplexer not including the first acoustic resonator (e.g., first acoustic resonator 122) and the second acoustic resonator (e.g., second acoustic resonator 132) may indicate intensity of a signal corresponding to −5 dB or less between the intensity 300 of the mid-band frequency signal of FIG. 3A and the intensity 310 of the high-band frequency signal. For example, intensity 344 of a mid-band frequency signal of FIG. 3B and intensity 342 of a high-band frequency signal may correspond to the intensity 300 of the mid-band frequency signal of FIG. 3A and the intensity 310 of the high-band frequency signal. For example, intensity 354 of the mid-band frequency signal of FIG. 3B and intensity 352 of the high-band frequency signal may correspond to a portion of −5 dB or less in the intensity 300 of the mid-band frequency signal of FIG. 3A and the intensity 310 of the high-band frequency signal.

According to an embodiment, referring to FIG. 3A together, the signal intensity graph 350 for each frequency corresponding to the diplexer (e.g., diplexer 100) including the first acoustic resonator (e.g., first acoustic resonator 122) and the second acoustic resonator (e.g., second acoustic resonator 132) may indicate intensity of a signal corresponding to −5 dB or less between the intensity 300 of the mid-band frequency signal of FIG. 3A and the intensity 330 of the high-band frequency signal. For example, the intensity 354 of the mid-band frequency signal of FIG. 3B and the intensity 352 of the high-band frequency signal may correspond to the intensity 320 of the mid-band frequency signal of FIG. 3A and the intensity 330 of the high-band frequency signal. For example, the intensity 354 of the mid-band frequency signal of FIG. 3B and the intensity 352 of the high-band frequency signal may correspond to a portion of −5 dB or less in the intensity 300 of the mid-band frequency signal of FIG. 3A and the intensity 310 of the high-band frequency signal.

According to an embodiment, referring to the signal intensity graph 340 for each frequency corresponding to the diplexer not including the first acoustic resonator (e.g., first acoustic resonator 122) and the second acoustic resonator (e.g., second acoustic resonator 132), the intensity 344 of the mid-band frequency signal and the intensity 342 of the high-band frequency signal may indicate a decrease in signal intensity at a first cut-off frequency I1 and a second cut-off frequency I2. In an example, the first cut-off frequency I1 may correspond to a first cut-off frequency of the first LC filter (e.g., first LC filter 124) and the second cut-off frequency I2 may correspond to a second cut-off frequency of the second LC filter 134.

According to an embodiment, referring to the signal intensity graph 340 for each frequency corresponding to the diplexer not including the first acoustic resonator (e.g., first acoustic resonator 122) and the second acoustic resonator (e.g., second acoustic resonator 132), the intensity 344 of the mid-band frequency signal and the intensity 342 of the high-band frequency signal may indicate a decrease in signal intensity at the first cut-off frequency I1 and the second cut-off frequency I2. For example, the first cut-off frequency I1 may correspond to 2050 MHz. For the first cut-off frequency I1, the intensity 344 of the mid-band frequency signal may have an intensity of −0.1432 dB and the intensity 342 of the high-band frequency signal may have an intensity of −45.07 dB. For example, the second cut-off frequency I2 may correspond to 2500 MHz. For the second cut-off frequency I2, the intensity 344 of the mid-band frequency signal may have an intensity of −58.94 dB and the intensity 342 of the high-band frequency signal may have an intensity of −0.1354 dB.

According to an embodiment, referring to the signal intensity graph 350 for each frequency corresponding to the diplexer (e.g., diplexer 100) including the first acoustic resonator (e.g., first acoustic resonator 122) and the second acoustic resonator (e.g., second acoustic resonator 132), the intensity 354 of the mid-band frequency signal and the intensity 352 of the high-band frequency signal may indicate a decrease in signal intensity at a cut-off frequency f2 of the first LC filter (e.g., first LC filter 124) and a cut-off frequency f3 of the second LC filter (e.g., second LC filter 134). In an example, the intensity 354 of the mid-band frequency signal may be blocked at a center frequency f3′ of a frequency band to be cut off by the first acoustic resonator (e.g., first acoustic resonator 122), due to the first acoustic resonator (e.g., first acoustic resonator 122). Furthermore, the intensity 352 of the high-band frequency signal may be blocked at a center frequency f2′ of a frequency band to be cut off by the second acoustic resonator (e.g., second acoustic resonator 132), due to the second acoustic resonator (e.g., second acoustic resonator 132). In an example, the cut-off frequency f2 of the first LC filter (e.g., first LC filter 124) may correspond to a first specified frequency f2. In an example, the cut-off frequency f3 of the second LC filter (e.g., second LC filter 134) may correspond to a second specified frequency f2. According to an embodiment, referring to the signal intensity graph 350 for each frequency corresponding to the diplexer (e.g., diplexer 100) including the first acoustic resonator (e.g., first acoustic resonator 122) and the second acoustic resonator (e.g., second acoustic resonator 132), the cut-off frequency f2 may correspond to the cut-off frequency of the first LC filter (e.g., first LC filter 124). For example, the cut-off frequency f2 may correspond to a frequency corresponding to a point where the intensity 354 of the mid-band frequency signal is reduced by about 3 dB. In an example, the cut-off frequency f3 may correspond to the cut-off frequency of the second LC filter 134. For example, the cut-off frequency f3 may correspond to a frequency corresponding to a point where the intensity 352 of the high-band frequency signal is reduced by about 3 dB.

According to an embodiment, the mid-band frequency signal may be blocked at the frequency f3′, due to the first acoustic resonator (e.g., first acoustic resonator 122). In an example, the mid-band frequency signal may correspond to an open state on the basis of a Smith chart, at the frequency f3′. In an example, the high-band frequency signal may be blocked at the frequency f2′, due to the second acoustic resonator (e.g., second acoustic resonator 132). In an example, the high-band frequency signal may correspond to an open state on the basis of the Smith chart, at the frequency f2′.

According to an embodiment, the diplexer (e.g., diplexer 100) may be configured such that the cut-off frequency f2 corresponds to 2150 MHz and the cut-off frequency f3 corresponds to 2350 MHz. According to an embodiment, the diplexer (e.g., diplexer 100) may be configured such that a frequency difference between the cut-off frequency f2 and the cut-off frequency f3 corresponds to 200 MHz. A frequency corresponding to the cut-off frequency f2 and the cut-off frequency f3 according to the present example is only an example and is not limited to a certain frequency. The cut-off frequency f2 and the cut-off frequency f3 may have frequencies different from the frequencies given as examples, based on the configuration of the first filter circuit (e.g., first filter circuit 120) and the second filter circuit (e.g., second filter circuit 130) of the diplexer (e.g., diplexer 100).

According to an embodiment, the diplexer (e.g., diplexer 100) may set the frequency f2′ and the frequency f3′ to be adjacent to the cut-off frequency f2 and the cut-off frequency f3 to optimize a signal separation characteristic. In an example, the cut-off frequency f2 may be less than or equal to the frequency f2′. In an example, the cut-off frequency f3 may be greater than or equal to the frequency f3′. For example, referring to the signal intensity graph 350 for each frequency corresponding to the diplexer including the first acoustic resonator (e.g., first acoustic resonator 122) and the second acoustic resonator (e.g., second acoustic resonator 132), the cut-off frequency f2 of the first LC filter (e.g., first LC filter 124), the center frequency f2′ of a frequency band to be cut off by the second acoustic resonator (e.g., second acoustic resonator 132), the center frequency f3′ of a frequency band to be cut off by the first acoustic resonator (e.g., first acoustic resonator 122), and the cut-off frequency of the second LC filter (e.g., second LC filter 134) may establish an equation of f2<=f2′<f3′<=f3. According to an embodiment, the diplexer (e.g., diplexer 100) may set the frequency f2′ and the cut-off frequency f2 to be adjacent to each other and may set the frequency f3′ and the cut-off frequency f3 to be adjacent to each other. According to an embodiment, the diplexer (e.g., diplexer 100) may be configured such that a frequency difference between the cut-off frequency f2 and the cut-off frequency f3 corresponds to 100 MHz. For example, the cut-off frequency f2 may correspond to 2200 MHz. For the cut-off frequency f2, the intensity 354 of the mid-band frequency signal may have an intensity of −0.1246 dB and the intensity 352 of the high-band frequency signal may have an intensity of −38.93 dB. For example, the cut-off frequency f3 may correspond to 2300 MHz. For the cut-off frequency f3, the intensity 354 of the mid-band frequency signal may have an intensity of −44.52 dB and the intensity 352 of the high-band frequency signal may have an intensity of −0.008371 dB.

According to an embodiment, the diplexer not including the first acoustic resonator (e.g., first acoustic resonator 122) and the second acoustic resonator (e.g., second acoustic resonator 132) may have a configuration including an inductor and a capacitor. At this time, a frequency bandwidth value of a frequency to be cut off, compared to a center frequency value of the frequency to be cut off by the diplexer, may correspond to a result value of (I2−I1)/((I1+I2)/2). For example, the diplexer not including the first acoustic resonator (e.g., first acoustic resonator 122) and the second acoustic resonator (e.g., second acoustic resonator 132) may correspond to a value of about 19%, due to a formula of (2500−2050)/((2050+2500)/2)=0.1978.

According to an embodiment, the diplexer including the first acoustic resonator (e.g., first acoustic resonator 122) and the second acoustic resonator (e.g., second acoustic resonator 132) may have a configuration including the acoustic resonator (e.g., first acoustic resonator 122, second acoustic resonator 132) other than the inductor and the capacitor. At this time, the frequency bandwidth value of the frequency to be cut off, compared to the center frequency value of the frequency to be cut off by the diplexer, may correspond to a result value of (f3−f2)/((f2+f3)/2). For example, the diplexer including the first acoustic resonator (e.g., first acoustic resonator 122) and the second acoustic resonator (e.g., second acoustic resonator 132) may correspond to a value of about 4%, due to a formula of (2300−2200)/((2200+2300)/2)=0.0444.

According to an embodiment, the diplexer not including the first acoustic resonator (e.g., first acoustic resonator 122) and the second acoustic resonator (e.g., second acoustic resonator 132) may have an adjacent frequency separation characteristic value of about 20%. Furthermore, when using a ceramic pattern with high permittivity, the diplexer may have an adjacent frequency separation characteristic value of about 15%. In an example, as the adjacent frequency separation characteristic value of the diplexer corresponds to lower %, it may correspond to a diplexer which separates an adjacent frequency signal such that an insertion loss of the adjacent frequency signal is small, in a narrower band.

According to an embodiment, the diplexer including the first acoustic resonator (e.g., first acoustic resonator 122) and the second acoustic resonator (e.g., second acoustic resonator 132) may have a lower adjacent frequency separation characteristic value than the diplexer not including the first acoustic resonator (e.g., first acoustic resonator 122) and the second acoustic resonator (e.g., second acoustic resonator 132). In an example, the diplexer including the first acoustic resonator (e.g., first acoustic resonator 122) and the second acoustic resonator (e.g., second acoustic resonator 132) may have an adjacent frequency separation characteristic value of a level less than 15%. For example, the diplexer not including the first acoustic resonator (e.g., first acoustic resonator 122) and the second acoustic resonator (e.g., second acoustic resonator 132) may have an adjacent frequency separation characteristic value of about 4%. In an example, the diplexer including the first acoustic resonator (e.g., first acoustic resonator 122) and the second acoustic resonator (e.g., second acoustic resonator 132) may separate the adjacent frequency signal such that the insertion loss of the adjacent frequency signal is small, in a narrower band, than a diplexer which distinguishes adjacent frequencies by simply using the inductor and the capacitor.

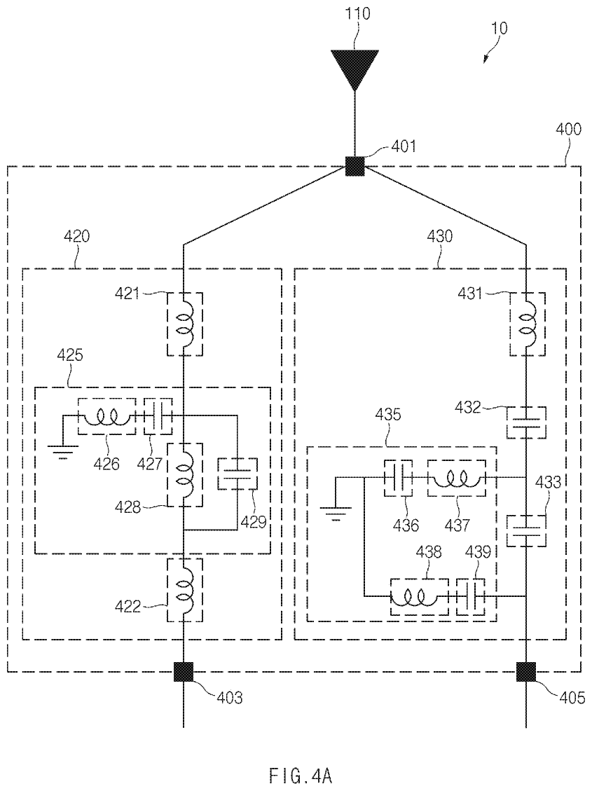

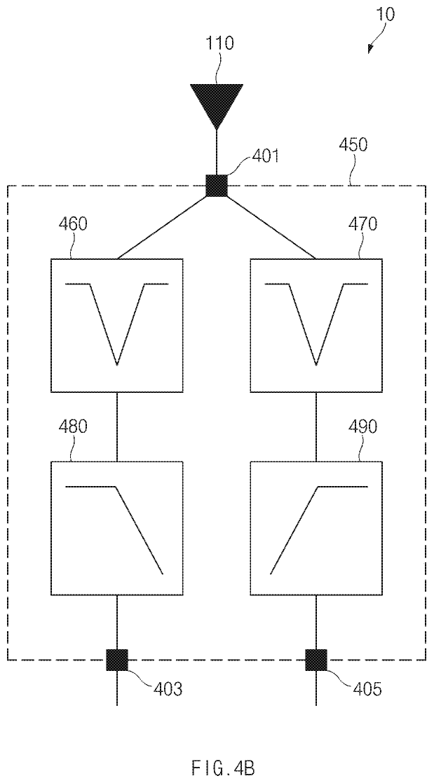

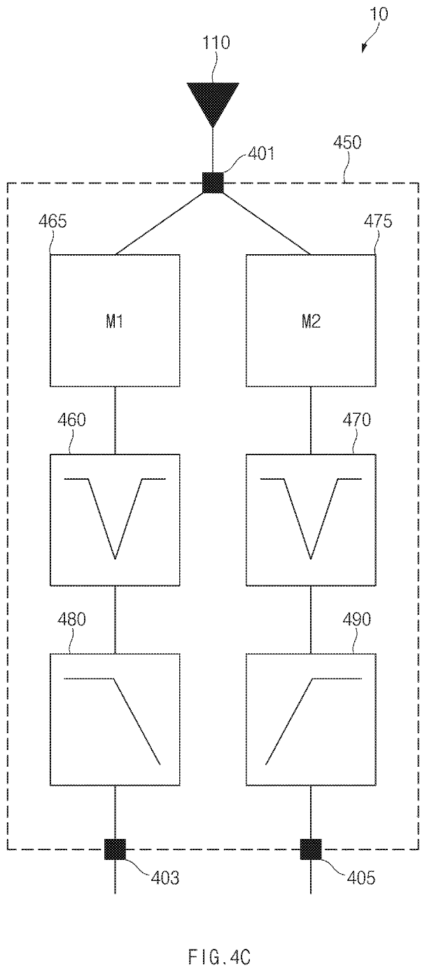

FIGS. 4A, 4B, and 4C are drawings illustrating a configuration of a diplexer according to various embodiments of the disclosure.

Referring to FIG. 4A, a diplexer 400 may include a first filter circuit 420, a second filter circuit 430, a first terminal 401 for connecting the first filter circuit 420, the second filter circuit 430, and an antenna 110, a second terminal 403 to which a first RF signal is applied, and a third terminal 405 to which a second RF signal is applied.

According to an embodiment, the diplexer 400 may include radio frequency (RF) elements. For example, the first filter circuit 420 of the diplexer 400 may include an inductor (e.g., inductors 421, 422, 426, and 428) or a capacitor (e.g., capacitors 427 and 429). For example, the second filter circuit 430 of the diplexer 400 may include an inductor (e.g., inductors 431, 437, and 438) or a capacitor (e.g., capacitors 432, 433, 436, and 439). In an example, configurations of the diplexer 400, which will be described below in conjunction with FIG. 4A, are an example and embodiments of the disclosure are not limited thereto. For example, the diplexer 400 may fail to include at least some (e.g., inductor 422, capacitor 432) of the configurations illustrated in FIG. 4A. For example, the diplexer 400 may further include another configuration (e.g., an additional inductor or an additional capacitor) other than the configurations illustrated in FIG. 4A.

According to an embodiment, referring to FIG. 1 together, the diplexer 400 of FIG. 4A may correspond to a diplexer 100 of FIG. 1. in an example, the first terminal 401 for connecting the first filter circuit 420, the second filter circuit 430, and the antenna 110 of FIG. 4A, the second terminal 403 to which the first RF signal is applied, and the third terminal 405 to which the second RF signal is applied may correspond to a first terminal 101, a second terminal 103, and a third terminal 105 of FIG. 1.

According to an embodiment, when performing frequency separation in an interval where two bands are adjacent to each other using the diplexer 400 based on a ceramic element or an inductor and a capacitor element, trade-off may occur between band rejection and an insertion loss for a relative frequency between the first filter circuit 420 and the second filter circuit 430. For example, a loss in a separated boundary band may increase to about 4~5 dB, according to the configuration of a front end module 200. In an example, the first terminal 401 for connecting the first filter circuit 420, the second filter circuit 430, and the antenna 110 may correspond to the first terminal 101 of FIG. 1.

According to an embodiment, when increasing a loss to improve isolation of a band, radiation performance of an electronic device 10 may be reduced due to a loss of transmit power. For example, an output of a power amplifier on a transmit path may increase to compensate for the loss of the transmit power. In this case, a power loss of the electronic device 10 may increase and heat generation of a terminal may also increase. In an example, when reducing a rejection characteristic for a frequency band for frequency separation to reduce loss power, interference may occur between two frequency signals. For example, when signals of a first frequency and a second frequency are simultaneously transmitted from the electronic device 10, a leakage component of a first frequency signal component may generate interference for the second frequency signal or a leakage component of a second frequency signal component may generate interference for the first frequency signal. In this case, receiving sensitivity of a receiving terminal may be reduced due to the interference. For compensation of the receiving sensitivity, when the transmit power of the terminal increases, a power loss and heat generation of the terminal may increase.

According to an embodiment, for a resonator (e.g., a serial/parallel notch) of a filter, such as the diplexer 400 including an inductor including a ceramic element and a capacitor, examples of the disclosure may use a band stop filter (e.g., an acoustic resonator) in at least a partial area (e.g., partial area 425) of the first filter circuit 420 and at least a partial area (e.g., partial area 435) of the second filter circuit 430 and may simultaneously connect a path of the first terminal 401 between two band stop filters in the direction of the antenna 110 to ensure an adjacent band rejection characteristic, thus reducing an insertion loss and improving a band rejection characteristic (e.g., band isolation). According to an embodiment, referring to FIG. 1 together, the first filter circuit 420 of FIG. 4A may correspond to a first filter circuit 120 of FIG. 1. In an example, the second filter circuit 430 of FIG. 4A may correspond to a second filter circuit 130 of FIG. 1.

In an example, the acoustic resonator may include a thin film bulk acoustic resonator (TFBAR) or a film bulk acoustic resonator (FBAR). For example, the acoustic resonator may include a piezo element located between two film layers.

According to an embodiment, the first filter circuit 420 may correspond to a circuit for passing a signal with a frequency lower than the set cut-off frequency. In an example, referring to FIG. 1 together, the first filter circuit 420 may correspond to the first filter circuit 120 and other circuit configurations may be added or replaced in the at least a partial area 425 of the first filter circuit 420. For example, a notch filter or a band reject filter may be added to the at least a partial area 425 of the first filter circuit 420.

According to an embodiment, the second filter circuit 430 may correspond to a circuit for passing a signal with a frequency higher than the set cut-off frequency. In an example, referring to FIG. 1 together, the second filter circuit 430 may correspond to the second filter circuit 130 of FIG. 1 and other circuit configurations may be added or replaced in the at least a partial area 435 of the second filter circuit 430. For example, a notch filter or a band reject filter may be added to the at least a partial area 435 of the second filter circuit 430.

The first acoustic resonator 122 and the second acoustic resonator 132 according to an embodiment may include an acoustic resonator. Referring to FIG. 4B, a diplexer 450 may include a first band stop filter 460, a second band stop filter 470, a low pass filter 480, and a high pass filter 490. Furthermore, the diplexer 450 may include a first terminal 401 connected with the antenna 110, the first band stop filter 460, and the second band stop filter 470, a second terminal 403 to which a first RF signal is applied, and a third terminal 405 to which a second RF signal is applied.

According to an embodiment, referring to FIG. 4A together, the first band stop filter 460 and the low pass filter 480 of FIG. 4B may correspond to a configuration included in the first filter circuit 420 of FIG. 4A. For example, the first band stop filter 460 of FIG. 4B may correspond to at least a partial area (e.g., partial area 425) of the first filter circuit 420 of FIG. 4A. In an example, the second band stop filter 470 and the high pass filter 490 of FIG. 4B may correspond to the second filter circuit 430 of FIG. 4A. For example, the second band stop filter 470 of FIG. 4B may correspond to at least a partial area (e.g., partial area 435) of the second filter circuit 430 of FIG. 4A. In an example, the first band stop filter 460 or the second band stop filter 470 may correspond to an acoustic resonator. In an example, the diplexer 450 may increase a band rejection characteristic of a frequency band which should be separated using the acoustic resonator and may simultaneously improve an insertion loss of a pass band. In an example, the band stop filter may correspond to a notch filter.

According to an embodiment, a notch filter part compared to an existing diplexer may be formed of a high Q acoustic filter. A band rejection characteristic of a frequency band which should be separated using the acoustic filter (e.g., the acoustic resonator) may increase and an insertion loss of a pass band may be simultaneously improved.

In order to do so, a signal may be delivered in the direction of the high pass filter 490 from the first terminal 401 and signal delivery is not performed in the direction of the low pass filter 480 to have a high band rejection characteristic at the lowest frequency f2′ in the pass band of the high pass filter 490 at a terminal side of a path passing through the low pass filter 480 and to appear as open on the Smith chart when looking at the corresponding notch filter (e.g., the first band stop filter 460) from the first terminal 401 (to substantially appear as an open state (have an impedance value of threshold impedance or more for the frequency f2′) when looking at the low pass filter 480 from the first terminal 401 for the frequency f2′).

On the other hand, an acoustic notch for blocking a band of the highest frequency f3′ of the low pass filter 480 may be located between the first terminal 401 and a path passing through the high pass filter 490. As this appears as open on the Smith chart at the corresponding frequency, an acoustic resonator notch may be located as in FIG. 4B, such that the intermediate high pass filter 490 to which the signal between the terminal and the low pass filter 480 is delivered does not appear due to the corresponding notch (e.g., the second band stop filter 470). In this case, it may have a characteristic of a high Q acoustic filter, compared to an existing combination of a low pass filter and a high pass filter. For example, it is expected to separate low-and mid-band signals or mid-and high-band signals at a lower loss. In an example, a center frequency of a frequency band blocked by the first band stop filter 460 may correspond to f3′ and a center frequency of a frequency band blocked by the second band stop filter 470 may correspond to f2′.

According to an embodiment, referring to FIG. 1 together, the first band stop filter 460 of FIG. 4B may correspond to a first acoustic resonator 122 of FIG. 1. In an example, the first band stop filter 460 may be located between the first terminal 401 and the low pass filter 480. In an example, the first band stop filter 460 may sharply generate a degree to which the intensity of the first frequency signal is reduced by the low pass filter 480, for the first frequency signal passed by the low pass filter 480. For example, the first band stop filter 460 may reduce a transition bandwidth of the first frequency signal.

According to an embodiment, referring to FIG. 1 together, the second band stop filter 470 of FIG. 4B may correspond to a second acoustic resonator 132 of FIG. 1. In an example, the second band stop filter 470 may be located between the first terminal 401 and the high pass filter 490. In an example, the second band stop filter 470 may sharply generate a degree to which the intensity of the second frequency signal is reduced by the high pass filter 490, for the second frequency signal passed by the high pass filter 490. For example, the second band stop filter 470 may reduce a transition bandwidth of the second frequency signal.

According to an embodiment, the transition bandwidth(s) of the first frequency signal and/or the second frequency signal may be reduced by the first band stop filter 460 located between the low pass filter 480 and the first terminal 401 and/or the second band stop filter 470 located between the high pass filter 490 and the first terminal 401, among the configurations of the diplexer 450. Due to this, a band rejection characteristic may be improved and an insertion loss may simultaneously be alleviated.

Referring to FIG. 4C, the diplexer 450 may include the first band stop filter 460, the second band stop filter 470, the low pass filter 480, the high pass filter 490, the first terminal 401 connected with the antenna 110, the first band stop filter 460, and the second band stop filter 470, the second terminal 403 to which the first RF signal is applied, and/or the third terminal 405 to which the second RF signal is applied. For example, the diplexer 450 may include a first matching element 465 connected between the first terminal 401 and the first band stop filter 460 and may include a second matching element 475 connected between the first terminal 401 and the second band stop filter 470.

According to an embodiment, the first matching element 465 may vary matching of the first band stop filter 460 to change a frequency pass characteristic of the first band stop filter 460. According to an embodiment, the first matching element 465 may reduce a loss of signals passing through the first band stop filter 460 via impedance matching of the first band stop filter 460 and may increase transmission efficiency of a target frequency (e.g., low-band frequency or mid-band frequency) signal. In an example, referring to FIG. 4A together, the diplexer 400 may further a matching element (e.g., first matching element 465). In an example, the matching element (e.g., first matching element 465) included in the diplexer 400 may vary matching of the first filter circuit 420 of FIG. 4A to change a frequency pass characteristic of the first filter circuit 420. In an example, the first matching element 465 may include at least one inductor and/or a capacitor.

According to an embodiment, the second matching element 475 may vary matching of the second band stop filter 470 to change a frequency pass characteristic of the second band stop filter 470. For example, the second matching element 475 may reduce a loss of signals passing through the second band stop filter 470 via impedance matching of the second band stop filter 470 and may increase transmission efficiency of a target frequency (e.g., mid-band frequency or high-band frequency) signal. In an example, referring to FIG. 4A together, the diplexer 400 may further a matching element (e.g., second matching element 475). In an example, the matching element (e.g., second matching element 475) included in the diplexer 400 may vary matching of the second filter circuit 430 of FIG. 4A to change a frequency pass characteristic of the second filter circuit 430. In an example, the second matching element 475 may include at least one capacitor and/or an inductor.

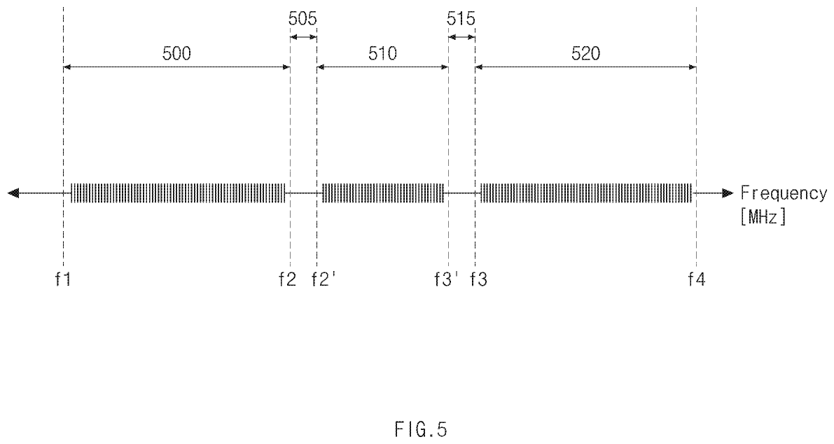

FIG. 5 illustrates frequency bands of signals transmitted and received by an electronic device according to an embodiment of the disclosure.

Referring to FIG. 5, the frequency bands of the signals transmitted and received by the electronic device may include a first frequency band 500, a second frequency band 520, or a band stop band 510 including a band in which a band rejection characteristic appears by a first band stop filter 460 and a second band stop filter 470. In an example, a frequency interval 505 between a frequency f2 and a frequency f2′ of FIG. 5 may be greater than or equal to 0. In an example, the frequency f2′ may be greater than or equal to the frequency f2. In an example, a frequency interval 515 between a frequency f3′ and a frequency f3 of FIG. 5 may be greater than or equal to 0. For example, the frequency f3 may be greater than or equal to the frequency f3′.

According to an embodiment, referring to FIG. 3B together, the frequency f2 of FIG. 5 may correspond to a cut-off frequency f2 of a first LC filter (e.g., first LC filter 124), the frequency f2′ of FIG. 5 may correspond to a center frequency f2′ of a frequency band to be cut off by a second acoustic resonator (e.g., second acoustic resonator 132), the frequency f3′ of FIG. 5 may correspond to a center frequency f3′ of a frequency band to be cut off by a first acoustic resonator (e.g., first acoustic resonator 122), and the frequency f3 of FIG. 5 may correspond to a cut-off frequency f3 of a second LC filter (e.g., second LC filter 134). In an example, the center frequency f2′ of the frequency band to be cut off by the second acoustic resonator (e.g., second acoustic resonator 132) may correspond to the center frequency f2′ of the frequency band to be cut off by the second band stop filter (e.g., second band stop filter 470) and the center frequency f3′ of the frequency band to be cut off by the first acoustic resonator (e.g., first acoustic resonator 122) may correspond to the center frequency f3′ of the frequency band to be cut off by the first band stop filter 460.

According to an embodiment, when an antenna should support signals of different bands and/or different characteristics, for example, the disclosure may expect the effect of ensuring an adjacent band rejection characteristic of an adjacent frequency using an acoustic resonator-based filter and maintaining performance of a band with a relatively wide frequency interval using a low pass filter and a high pass filter based on an inductor including a ceramic element and a capacitor to show a more improved pass characteristic and band rejection characteristic in case of separation between ultra-wideband (UWB) and wireless fidelity (Wi-Fi™), between Sub6 and UWB/fifth generation (5G) Wi-Fi, between a mid-band signal and a high-band signal.

According to an embodiment, referring to FIG. 4B together, the first frequency band 500 may correspond to a frequency band of the first frequency signal to be passed by a low pass filter 480. In an example, the first frequency band 500 may include the lowest frequency band among frequency bands passed by a high pass filter 490. In an example, the highest frequency f2 of the first frequency band 500 may correspond to a frequency adjacent to the center frequency f2′ of the frequency band to be cut off by the second band stop filter 470. In an example, the highest frequency f2 of the first frequency band 500 may be lower than the center frequency f2′ of the frequency band to be cut off by the second band stop filter 470.

According to an embodiment, the first frequency band 500 may correspond to the frequency band of the first frequency signal to be passed by a first band pass filter or the low pass filter (e.g., low pass filter 480). In an example, a frequency f1 may correspond to a frequency lower than the frequency f2 and the first band pass filter may correspond to a band pass filter for passing a frequency band corresponding to the frequency f2 at the frequency f1.

According to an embodiment, the band stop band 510 may include a frequency band to be cut off by the first band stop filter 460 and/or the second band stop filter 470. In an example, the lowest frequency f2′ of the band stop band 510 may correspond to a center frequency of a frequency band to be cut off by the second band stop filter 470. In an example, the highest frequency f3′ of the band stop band 510 may correspond to a center frequency of a frequency band to be cut off by the first band stop filter 460.

According to an embodiment, the second frequency band 520 may correspond to a frequency band of a second frequency signal to be passed by the high pass filter 490. In an example, the second frequency band 520 may include the highest frequency band among frequency bands passed by the low pass filter 480. In an example, the lowest frequency f3 of the second frequency band 520 may correspond to a frequency adjacent to the center frequency f3′ of the frequency band to be cut off by the first band stop filter 460. In an example, the lowest frequency f3 of the second frequency band 520 may be higher than the center frequency f3′ of the frequency band to be cut off by the first band stop filter 460.

According to an embodiment, the second frequency band 520 may correspond to a frequency band of the second frequency signal to be passed by a second band pass filter or the high pass filter (e.g., high pass filter 490). In an example, a frequency f4 may correspond to a frequency higher than the frequency f3 and the second band pass filter may correspond to a band pass filter for passing a frequency band corresponding to the frequency f4 at the frequency f3.

According to an embodiment, the frequency band which corresponds to the frequency f3 at the frequency f2 may correspond to a fifth frequency band. In an example, the fifth frequency band may correspond to a frequency band to be cut off by the diplexer (e.g., diplexer 100). For example, the diplexer (e.g., diplexer 100) may set the frequency f2 as a cut-off frequency of the low pass filter and may set the frequency f3 as a cut-off frequency of the high pass filter. At this time, the frequency band which corresponds to the frequency f3 at the frequency f2 may be the fifth frequency band, which may correspond to a frequency band in which intensity of a signal passing through the diplexer (e.g., diplexer 100) is more reduced than a frequency band which corresponds to the frequency f2 at the frequency f1 or a frequency band which corresponds to the frequency f4 at the frequency f3.

The first frequency band 500, the band stop band 510, and the second frequency band 520 may be adjacent to each other or may include a frequency band which is common in at least a partial area.

The first band stop filter 460 according to an embodiment may cut off a third frequency band, the second band stop filter 470 may cut off a fourth frequency band, and the third frequency band may correspond to a frequency band higher than the fourth frequency band. In an example, the third frequency band and the fourth frequency band may be included in the band stop band 510.

The third frequency band according to an embodiment may correspond to a frequency band lower than the lowest frequency f3 of the second frequency band 520, while adjacent to the lowest frequency f3 of the second frequency band 520 and the fourth frequency band may correspond to a frequency band higher than the highest frequency f2 of the first frequency band 500, while adjacent to the highest frequency f2 of the first frequency band 500.

The third frequency band and the fourth frequency band according to an embodiment may be adjacent to each other or may include a frequency band which is common in at least a partial area.

The third frequency band according to an embodiment may be adjacent to a second specified frequency f3 to be lower than the second specified frequency f3 and the fourth frequency band may be adjacent to a first specified frequency f2 to be higher than the first specified frequency f2. The center frequency f3′ of the third frequency band according to an embodiment may be higher than the center frequency f2′ of the fourth frequency band.

The diplexer (e.g., diplexer 100) according to an embodiment may be configured not to pass a fifth frequency band corresponding to between the first specified frequency f2 and the second specified frequency f3. A bandwidth value of the fifth frequency band compared to a center frequency value of the fifth frequency band is set to about 10% or less.

Each of the first specified frequency f2 and the second specified frequency f3 according to an embodiment may be higher than about 2 GHz. A difference between the first specified frequency f2 and the second specified frequency f3 according to an embodiment may be less than or equal to about 200 MHz.

A first LC filter (e.g., first LC filter 124) according to an embodiment may be configured not to pass a frequency band lower than a third specified frequency f1. The third specified frequency f1 may be lower than the first specified frequency f2. A second LC filter 134 according to an embodiment may be configured not to pass a frequency band higher than the fourth specified frequency f4. The fourth specified frequency f4 may be higher than the second specified frequency f3.

FIG. 6 is a block diagram illustrating an electronic device in a network environment according to an embodiment of the disclosure.

Referring to FIG. 6, an electronic device 601 in a network environment 600 may communicate with an electronic device 602 via a first network 698 (e.g., a short-range wireless communication network), or at least one of an electronic device 604 or a server 608 via a second network 699 (e.g., a long-range wireless communication network). According to an embodiment, the electronic device 601 may communicate with the electronic device 604 via the server 608. According to an embodiment, the electronic device 601 may include a processor 620, memory 630, an input module 650, a sound output module 655, a display module 660, an audio module 670, a sensor module 676, an interface 677, a connecting terminal 678, a haptic module 679, a camera module 680, a power management module 688, a battery 689, a communication module 690, a subscriber identification module (SIM) 696, or an antenna module 697. In some embodiments, at least one of the components (e.g., the connecting terminal 678) may be omitted from the electronic device 601, or one or more other components may be added in the electronic device 601. In some embodiments, some of the components (e.g., the sensor module 676, the camera module 680, or the antenna module 697) may be implemented as a single component (e.g., the display module 660).

The processor 620 may execute, for example, software (e.g., a program 640) to control at least one other component (e.g., a hardware or software component) of the electronic device 601 coupled with the processor 620, and may perform various data processing or computation. According to one embodiment, as at least part of the data processing or computation, the processor 620 may store a command or data received from another component (e.g., the sensor module 676 or the communication module 690) in volatile memory 632, process the command or the data stored in the volatile memory 632, and store resulting data in non-volatile memory 634. According to an embodiment, the processor 620 may include a main processor 621 (e.g., a central processing unit (CPU) or an application processor (AP)), or an auxiliary processor 623 (e.g., a graphics processing unit (GPU), a neural processing unit (NPU), an image signal processor (ISP), a sensor hub processor, or a communication processor (CP)) that is operable independently from, or in conjunction with, the main processor 621. For example, when the electronic device 601 includes the main processor 621 and the auxiliary processor 623, the auxiliary processor 623 may be adapted to consume less power than the main processor 621, or to be specific to a specified function. The auxiliary processor 623 may be implemented as separate from, or as part of the main processor 621.

The auxiliary processor 623 may control at least some of functions or states related to at least one component (e.g., the display module 660, the sensor module 676, or the communication module 690) among the components of the electronic device 601, instead of the main processor 621 while the main processor 621 is in an inactive (e.g., sleep) state, or together with the main processor 621 while the main processor 621 is in an active state (e.g., executing an application). According to an embodiment, the auxiliary processor 623 (e.g., an image signal processor or a communication processor) may be implemented as part of another component (e.g., the camera module 680 or the communication module 690) functionally related to the auxiliary processor 623. According to an embodiment, the auxiliary processor 623 (e.g., the neural processing unit) may include a hardware structure specified for artificial intelligence model processing. An artificial intelligence model may be generated by machine learning. Such learning may be performed, e.g., by the electronic device 601 where the artificial intelligence is performed or via a separate server (e.g., the server 608). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 630 may store various data used by at least one component (e.g., the processor 620 or the sensor module 676) of the electronic device 601. The various data may include, for example, software (e.g., the program 640) and input data or output data for a command related thereto. The memory 630 may include the volatile memory 632 or the non-volatile memory 634.

The program 640 may be stored in the memory 630 as software, and may include, for example, an operating system (OS) 642, middleware 644, or an application 646.

The input module 650 may receive a command or data to be used by another component (e.g., the processor 620) of the electronic device 601, from the outside (e.g., a user) of the electronic device 601. The input module 650 may include, for example, a microphone, a mouse, a keyboard, a key (e.g., a button), or a digital pen (e.g., a stylus pen).

The sound output module 655 may output sound signals to the outside of the electronic device 601. The sound output module 655 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 660 may visually provide information to the outside (e.g., a user) of the electronic device 601. The display module 660 may include, for example, a display, a hologram device, or a projector and control circuitry to control a corresponding one of the display, hologram device, and projector. According to an embodiment, the display module 660 may include a touch sensor adapted to detect a touch, or a pressure sensor adapted to measure the intensity of force incurred by the touch.

The audio module 670 may convert a sound into an electrical signal and vice versa. According to an embodiment, the audio module 670 may obtain the sound via the input module 650, or output the sound via the sound output module 655 or a headphone of an external electronic device (e.g., the electronic device 602) directly or wirelessly coupled with the electronic device 601.

The sensor module 676 may detect an operational state (e.g., power or temperature) of the electronic device 601 or an environmental state (e.g., a state of a user) external to the electronic device 601, and then generate an electrical signal or data value corresponding to the detected state. According to an embodiment, the sensor module 676 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 677 may support one or more specified protocols to be used for the electronic device 601 to be coupled with the external electronic device (e.g., the electronic device 602) directly (e.g., wiredly) or wirelessly. According to an embodiment, the interface 677 may include, for example, a high definition multimedia interface (HDMI), a universal serial bus (USB) interface, a secure digital (SD) card interface, or an audio interface.

The connecting terminal 678 may include a connector via which the electronic device 601 may be physically connected with the external electronic device (e.g., the electronic device 602). According to an embodiment, the connecting terminal 678 may include, for example, an HDMI connector, a USB connector, an SD card connector, or an audio connector (e.g., a headphone connector).

The haptic module 679 may convert an electrical signal into a mechanical stimulus (e.g., a vibration or a movement) or electrical stimulus which may be recognized by a user via his tactile sensation or kinesthetic sensation. According to an embodiment, the haptic module 679 may include, for example, a motor, a piezoelectric element, or an electric stimulator.

The camera module 680 may capture a still image or moving images. According to an embodiment, the camera module 680 may include one or more lenses, image sensors, image signal processors, or flashes.

The power management module 688 may manage power supplied to the electronic device 601. According to one embodiment, the power management module 688 may be implemented as at least part of, for example, a power management integrated circuit (PMIC).

The battery 689 may supply power to at least one component of the electronic device 601. According to an embodiment, the battery 689 may include, for example, a primary cell which is not rechargeable, a secondary cell which is rechargeable, or a fuel cell.

The communication module 690 may support establishing a direct (e.g., wired) communication channel or a wireless communication channel between the electronic device 601 and the external electronic device (e.g., the electronic device 602, the electronic device 604, or the server 608) and performing communication via the established communication channel. The communication module 690 may include one or more communication processors that are operable independently from the processor 620 (e.g., the application processor (AP)) and supports a direct (e.g., wired) communication or a wireless communication. According to an embodiment, the communication module 690 may include a wireless communication module 692 (e.g., a cellular communication module, a short-range wireless communication module, or a global navigation satellite system (GNSS) communication module) or a wired communication module 694 (e.g., a local area network (LAN) communication module or a power line communication (PLC) module). A corresponding one of these communication modules may communicate with the external electronic device via the first network 698 (e.g., a short-range communication network, such as BluetoothTM, wireless-fidelity (Wi-Fi™) direct, or infrared data association (IrDA)) or the second network 699 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 692 may identify and authenticate the electronic device 601 in a communication network, such as the first network 698 or the second network 699, using subscriber information (e.g., international mobile subscriber identity (IMSI)) stored in the subscriber identification module 696.

The wireless communication module 692 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 692 may support a high-frequency band (e.g., the mmWave band) to achieve, e.g., a high data transmission rate. The wireless communication module 692 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 692 may support various requirements specified in the electronic device 601, an external electronic device (e.g., the electronic device 604), or a network system (e.g., the second network 699). According to an embodiment, the wireless communication module 692 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 697 may transmit or receive a signal or power to or from the outside (e.g., the external electronic device) of the electronic device 601. According to an embodiment, the antenna module 697 may include an antenna including a radiating element composed of a conductive material or a conductive pattern formed in or on a substrate (e.g., a printed circuit board (PCB)). According to an embodiment, the antenna module 697 may include a plurality of antennas (e.g., array antennas). In such a case, at least one antenna appropriate for a communication scheme used in the communication network, such as the first network 698 or the second network 699, may be selected, for example, by the communication module 690 (e.g., the wireless communication module 692) from the plurality of antennas. The signal or the power may then be transmitted or received between the communication module 690 and the external electronic device via the selected at least one antenna. According to an embodiment, another component (e.g., a radio frequency integrated circuit (RFIC)) other than the radiating element may be additionally formed as part of the antenna module 697.

According to various embodiments, the antenna module 697 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 601 and the external electronic device 604 via the server 608 coupled with the second network 699. Each of the electronic devices 602 or 604 may be a device of a same type as, or a different type, from the electronic device 601. According to an embodiment, all or some of operations to be executed at the electronic device 601 may be executed at one or more of the external electronic devices (e.g., the electronic device 602, electronic device 604, and the server 608). For example, if the electronic device 601 should perform a function or a service automatically, or in response to a request from a user or another device, the electronic device 601, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 601. The electronic device 601 may provide the outcome, with or without further processing of the outcome, as at least part of a reply to the request. To that end, a cloud computing, distributed computing, mobile edge computing (MEC), or client-server computing technology may be used, for example. The electronic device 601 may provide ultra low-latency services using, e.g., distributed computing or mobile edge computing. In another embodiment, the external electronic device 604 may include an internet-of-things (IoT) device. The server 608 may be an intelligent server using machine learning and/or a neural network. According to an embodiment, the external electronic device 604 or the server 608 may be included in the second network 699. The electronic device 601 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 640) including one or more instructions that are stored in a storage medium (e.g., internal memory 636 or external memory 638) that is readable by a machine (e.g., the electronic device 601). For example, a processor (e.g., the processor 620) of the machine (e.g., the electronic device 601) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

It will be appreciated that various embodiments of the disclosure according to the claims and description in the specification can be realized in the form of hardware, software or a combination of hardware and software.

Any such software may be stored in non-transitory computer readable storage media. The non-transitory computer readable storage media store one or more computer programs (software modules), the one or more computer programs include computer-executable instructions that, when executed by one or more processors of an electronic device individually or collectively, cause the electronic device to perform a method of the disclosure.

Any such software may be stored in the form of volatile or non-volatile storage such as, for example, a storage device like read only memory (ROM), whether erasable or rewritable or not, or in the form of memory such as, for example, random access memory (RAM), memory chips, device or integrated circuits or on an optically or magnetically readable medium such as, for example, a compact disk (CD), digital versatile disc (DVD), magnetic disk or magnetic tape or the like. It will be appreciated that the storage devices and storage media are various embodiments of non-transitory machine-readable storage that are suitable for storing a computer program or computer programs comprising instructions that, when executed, implement various embodiments of the disclosure. Accordingly, various embodiments provide a program comprising code for implementing apparatus or a method as claimed in any one of the claims of this specification and a non-transitory machine-readable storage storing such a program.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A diplexer, comprising:
a first terminal configured to be connected with an external radio frequency (RF) signal path of the diplexer;
a second terminal electrically connected with the first terminal via an internal first RF signal path of the diplexer;
a third terminal electrically connected with the first terminal via an internal second RF signal path;
a first filter circuit configured to form at least a portion of the first RF signal path and pass signals of a first frequency band lower than a first specified frequency; and
a second filter circuit configured to form at least a portion of the second RF signal path and pass signals of a second frequency band higher than a second specified frequency,
wherein the first filter circuit includes:
a first acoustic resonator configured not to pass a third frequency band, and
a first inductor and capacitor (LC) filter connected in series with the first acoustic resonator and configured to pass a frequency band lower than the first specified frequency,
wherein the second filter circuit includes:
a second acoustic resonator configured not to pass a fourth frequency band, and
a second LC filter connected in series with the second acoustic resonator and configured to pass a frequency band higher than the second specified frequency, and
wherein the first specified frequency is a frequency lower than the second specified frequency.

2. The diplexer of claim 1,
wherein the first filter circuit further includes an inductor connected between the first terminal and the first acoustic resonator, and
wherein the second filter circuit further includes a capacitor connected between the first terminal and the second acoustic resonator.

3. The diplexer of claim 1,
wherein the third frequency band is adjacent to the second specified frequency to be lower than the second specified frequency, and
wherein the fourth frequency band is adjacent to the first specified frequency to be higher than the first specified frequency.

4. The diplexer of claim 1, wherein a center frequency of the third frequency band is higher than a center frequency of the fourth frequency band.

5. The diplexer of claim 1,
wherein the diplexer is configured not to pass a fifth frequency band corresponding to between the first specified frequency and the second specified frequency, and
wherein a bandwidth value of the fifth frequency band compared to a center frequency value of the fifth frequency band is set to 10% or less.

6. The diplexer of claim 1, wherein each of the first specified frequency and the second specified frequency is higher than 2 gigahertz (GHz).

7. The diplexer of claim 1,
wherein the first LC filter is configured not to pass a frequency band lower than a third specified frequency, and
wherein the third specified frequency is lower than the first specified frequency.

8. The diplexer of claim 1,
wherein the second LC filter is configured not to pass a frequency band higher than a fourth specified frequency, and
wherein the fourth specified frequency is higher than the second specified frequency.

9. An apparatus for filtering a frequency of a signal, the apparatus comprising:
a plurality of terminals including a first terminal, a second terminal, and a third terminal;
a low band filter circuit including a first acoustic resonator and a first inductor and capacitor (LC) filter connected in series with each other between the first terminal and the second terminal; and
a high band filter circuit including a second acoustic resonator and a second LC filter connected in series with each other between the first terminal and the third terminal,
wherein the low band filter circuit is configured to pass a first signal portion corresponding to a first frequency band lower than a first specified frequency for an input signal,
wherein the high band filter circuit is configured to pass a second signal portion corresponding to a second frequency band higher than a second specified frequency for the input signal, and
wherein the first specified frequency is lower than the second specified frequency.

10. The apparatus of claim 9, wherein the first acoustic resonator forms at least a part of a first notch filter and the second acoustic resonator forms at least a part of a second notch filter.

11. The apparatus of claim 9,
wherein the first acoustic resonator is configured not to pass a third frequency band between the first frequency band and the second frequency band,
wherein the second acoustic resonator is configured not to pass a fourth frequency band between the first frequency band and the second frequency band, and
wherein the fourth frequency band includes a band, at least a portion of which is different from the third frequency band.

12. The apparatus of claim 11,
wherein the third frequency band is adjacent to the second specified frequency to be lower than the second specified frequency, and
wherein the fourth frequency band is adjacent to the first specified frequency to be higher than the first specified frequency.

13. The apparatus of claim 9,
wherein the low band filter circuit further includes an inductor connected between the first terminal and the first acoustic resonator, and
wherein the high band filter circuit further includes a capacitor connected between the first terminal and the second acoustic resonator.

14. The apparatus of claim 9,
wherein a fifth frequency band corresponding to between the first specified frequency and the second specified frequency is set not to pass, and
wherein a bandwidth value of the fifth frequency band compared to a center frequency value of the fifth frequency band is set to 10% or less.

15. A portable communication device, comprising:
an antenna;
a transceiver; and
a diplexing circuit,
wherein the diplexing circuit includes:
a first terminal connected with at least one of a radio frequency (RF) signal path connected with one of the antenna or the transceiver or an external RF signal path of the diplexing circuit,
a second terminal connected with the first terminal via an internal first RF signal path of the diplexing circuit,
a third terminal connected with the first terminal via an internal second RF signal path of the diplexing circuit,
a first filter circuit configured to form at least a portion of the first RF signal path and pass signals of a first frequency band lower than a first specified frequency, and
a second filter circuit configured to form at least a portion of the second RF signal path and pass signals of a second frequency band higher than a second specified frequency,
wherein the first specified frequency is a frequency lower than the second specified frequency,
wherein the first filter circuit includes:
a first acoustic resonator configured not to pass a third frequency band, and
a first inductor and capacitor (LC) filter connected in series with the first acoustic resonator and configured to pass a frequency band lower than the first specified frequency, and
wherein the second filter circuit includes:
a second acoustic resonator configured not to pass a fourth frequency band, and
a second LC filter connected in series with the second acoustic resonator and configured to pass a frequency band higher than the second specified frequency.

16. The portable communication device of claim 15,
wherein the first filter circuit further includes an inductor connected between the first terminal and the first acoustic resonator, and
wherein the second filter circuit further includes a capacitor connected between the first terminal and the second acoustic resonator.

17. The portable communication device of claim 15,
wherein the third frequency band is adjacent to the second specified frequency to be lower than the second specified frequency, and
wherein the fourth frequency band is adjacent to the first specified frequency to be higher than the first specified frequency.

18. The portable communication device of claim 15, wherein a center frequency of the third frequency band is higher than a center frequency of the fourth frequency band.

19. The portable communication device of claim 15,
wherein the diplexing circuit is configured not to pass a fifth frequency band corresponding to between the first specified frequency and the second specified frequency, and
wherein a bandwidth value of the fifth frequency band compared to a center frequency value of the fifth frequency band is set to 10% or less.

20. The portable communication device of claim 15, wherein each of the first specified frequency and the second specified frequency is higher than 2 gigahertz (GHz).
